(19) United States
(12) Patent Application Publication
(10) Pub. No.: US 2022/0382219 A1
(43) Pub. Date: Dec. 1, 2022

(54) EXTERIOR MEMBER, CASE AND TIMEPIECE

(71) Applicant: CASIO COMPUTER CO., LTD., Tokyo (JP)

(72) Inventor: Yoshiki NAKATSUKA, Tokyo (JP)

(73) Assignee: CASIO COMPUTER CO., LTD., Tokyo (JP)

(21) Appl. No.: 17/828,671

(22) Filed: May 31, 2022

(30) Foreign Application Priority Data
Jun. 1, 2021 (JP) 2021-092158
Jan. 26, 2022 (JP) 2022-010155

(51) Int. Cl. G04B 37/22; G04B 37/00

(52) U.S. Cl. CPC G04B 37/225; G04B 37/0008

(57) ABSTRACT

An exterior member including a first fiber resin body formed by a plurality of first fiber resin sheets being laminated, and a second fiber resin body formed by a plurality of second fiber resin sheets being laminated, in which the first fiber resin sheets of the first fiber resin body are laminated while being inclined with respect to the second fiber resin sheets of the second fiber resin body.

### CROSS-REFERENCE TO RELATED APPLICATIONS

This application is based upon and claims the benefit of priority from the prior Japanese Patent Applications No. 2021-092158, filed Jun. 1, 2021, and No. 2022-010155, filed Jan. 26, 2022, the entire contents of which are incorporated herein by reference.

### BACKGROUND

### 1. Technical Field

The technical field relates to an exterior member that is used for electronic devices such as wristwatches and portable information terminals, a case including the exterior member, and a timepiece including the case.

### 2. Description of the Related Art

An exterior member for wristwatches is known which has a structure where carbon fibers as reinforcement materials have been laminated in a front or back direction to form a carbon fiber-reinforced resin sheet, and thermosetting resins have been provided on the front and back surfaces of the carbon fiber-reinforced resin sheet, as described in Japanese Patent Application Laid-Open (Kokai) Publication No. 2005-114495.

### SUMMARY

An embodiment is an exterior member comprising: a first fiber resin body formed by a plurality of first fiber resin sheets being laminated; and a second fiber resin body formed by a plurality of second fiber resin sheets being laminated, wherein the first fiber resin sheets of the first fiber resin body are laminated while being inclined with respect to the second fiber resin sheets of the second fiber resin body.

The above and further objects and novel features of the present invention will more fully appear from the following detailed description when the same is read in conjunction with the accompanying drawings. It is to be expressly understood, however, that the drawings are for the purpose of illustration only and are not intended as a definition of the limits of the invention.

### BRIEF DESCRIPTION OF THE DRAWINGS

FIG. 1 is an enlarged perspective view showing an embodiment of a wristwatch;

FIG. 2 is an enlarged cross-sectional view showing amain portion of the wristwatch taken along the A-A arrow view in FIG. 1;

FIG. 3 is an enlarged perspective view showing a second exterior member of an exterior member for the wristwatch shown in FIG. 1;

FIG. 4 is an enlarged perspective view showing a main portion of the second exterior member cut and taken along the B-B arrow view in FIG. 3; and

FIG. 5 is an enlarged perspective view showing patterns formed by glass fiber layers in a first fiber-reinforced resin body of the second exterior member shown in FIG. 3.

### DETAILED DESCRIPTION OF THE PREFERRED EMBODIMENTS

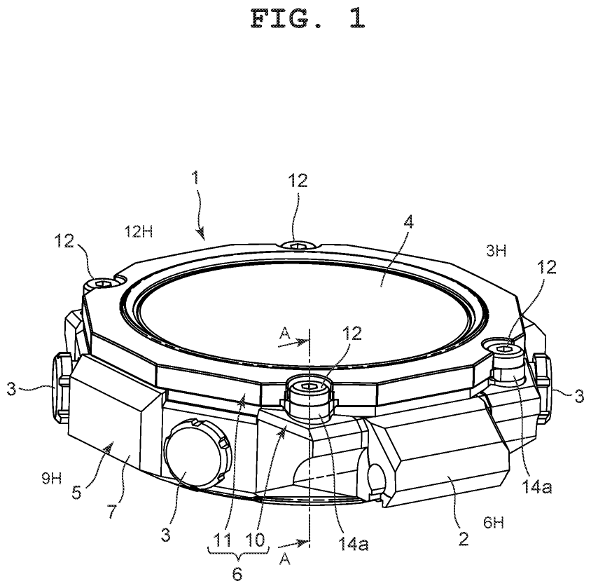

An embodiment where the present invention has been applied in a wristwatch will hereinafter be described with reference to FIG. 1 to FIG. 5.

This wristwatch includes a wristwatch case 1, as shown in FIG. 1. On the twelve o'clock side and six o'clock side of the wristwatch case 1, band attachment sections 2 are provided to which watch bands (not shown) are attached.

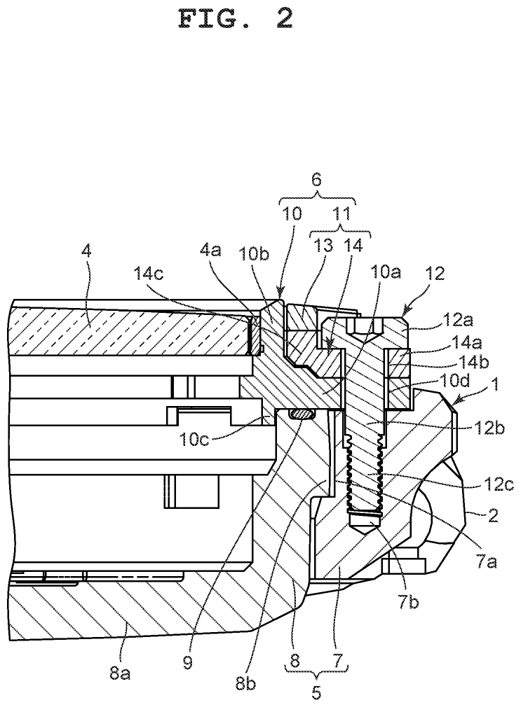

Also, on the two o'clock side, three o'clock side, four o'clock side, eight o'clock side, and ten o'clock side of the wristwatch case 1, switch buttons 3 are provided, as shown in FIG. 1. In the upper opening of the wristwatch case 1, a watch glass 4 is attached via a packing 4a, as shown in FIG. 2. Inside this wristwatch case 1, a timepiece module (not shown) is provided.

This wristwatch case 1 includes a case main body 5 and an exterior member 6, as shown in FIG. 1 and FIG. 2. The case main body 5 includes an outer case 7 and an inner case 8, of which the outer case 7 is made of a metal such as stainless steel and has a substantially ring shape. On the twelve o'clock side and six o'clock side of this outer case 7, the band attachment sections 2 are provided. The inner case 8, which has a substantially cylindrical shape, is made of a hard synthetic resin and has a bottom section 8a that serves as a back cover.

In this embodiment, the inner case 8 is formed such that its outer diameter is substantially equal to the inner diameter of the outer case 7 and its length in a vertical direction is longer than the length of the outer case 7 in the vertical direction, as shown in FIG. 2. On the side surface of the inner case 8, a projection section 8b is formed. When the inner case 8 is arranged in the outer case 7, this projection section 8b is inserted into and engages with a recess section 7a formed in the inner surface of the outer case 7, whereby the inner case 8 is prevented from being downwardly slipped out from the outer case 7.

The exterior member 6 includes a first exterior member 10 and a second exterior member 11, as shown in FIG. 1 and FIG. 2. The first exterior member 10, which is made of a metal such as stainless steel, has a substantially ring shape as a whole, and includes a ring-shaped plate section 10a which is arranged on and straddles the upper end surface of the outer case 7 and the upper end surface of the inner case 8, and a cylindrical section 10b which is formed on the inner circumferential portion of the plate section 10a and into which the watch glass 4 is fitted via the packing 4a.

In an area between the lower surface of the plate section 10a of the first exterior member 10 and the upper end surface of the inner case 8, a waterproof ring 9 is provided, as shown in FIG. 2. Also, on the inner circumferential rim of the plate section 10a of the first exterior member 10, a restriction section 10c is formed which comes in contact with the inner circumferential surface of the inner case 8. As a result, the first exterior member 10 is structured such that, when the plate section l0a is arranged on and straddles the upper end surface of the outer case 7 and the upper end surface of the inner case 8 via the waterproof ring 9, the restriction section 10c comes in contact with the inner circumferential surface of the inner case 8, whereby the position of the first exterior member 10 in radial directions is restricted.

The second exterior member 11, which is made of resin materials described later and has a substantially ring shape, is structured to be arranged on the plate section l0a of the first exterior member 10, as shown in FIG. 1 and FIG. 2. More specifically, the second exterior member 11 is formed such that its inner diameter is equal to the outer diameter of the cylindrical section 10b of the first exterior member 10 and its outer diameter is substantially equal to the outer diameter of the plate section l0a of the first exterior member 10.

Also, the second exterior member 11 is formed such that its length (thickness) in the vertical direction is slightly shorter (lower) than the length of the cylindrical section 10b of the first exterior member 10 in the vertical direction, as shown in FIG. 2. By this structure, the second exterior member 11 is arranged on the plate section 10a of the first exterior member 10 with its upper surface being positioned slightly lower than the upper end of the cylindrical section 10b of the first exterior member 10. As a result, the first exterior member 10 is structured such that impacts from above are received by the upper end of the cylindrical section 10b thereof and not exerted onto the upper surface of the second exterior member 11.

The second exterior member 11 arranged on the plate section 10a of the first exterior member 10 is attached to the case main body 5 together with the first exterior member 10 by a plurality of screw members 12 which is fastening members described later, as shown in FIG. 2. That is, the wristwatch case 1 is structured such that, in a state where the inner case 8 has been arranged in the outer case 7 and the first exterior member 10 has been arranged on the upper surfaces of the outer case 7 and the inner case 8, the second exterior member 11 is attached to the outer case 7 by the plurality of screw members 12 with the first exterior member 10 being held therebetween. The second exterior member 11 has a substantially ring shape as a whole by a first fiber-reinforced resin body 13 and a second fiber-reinforced resin body 14, as shown in FIG. 1 to FIG. 4. The first fiber-reinforced resin body 13 is formed by a plurality of first fiber-reinforced resin sheets being laminated. These first fiber-reinforced resin sheets are glass fiber layers S1 which are glass fiber-reinforced resin sheets using glass fibers as reinforcement materials.

More specifically, the first fiber-reinforced resin body 13 is a glass fiber-reinforced resin sheet body (GFRP) formed by the glass fiber layers S1, which are the first fiber-reinforced resin sheets, being laminated while being inclined at a predetermined inclination angle with reference to a thickness direction of the first fiber-reinforced resin body 13 which is a front or back direction, as shown in FIG. 1 to FIG. 4. This first fiber-reinforced resin body 13 includes a front surface section 13a and a side surface section 13b, and its cross-section has a substantially eave shape (inverted L shape).

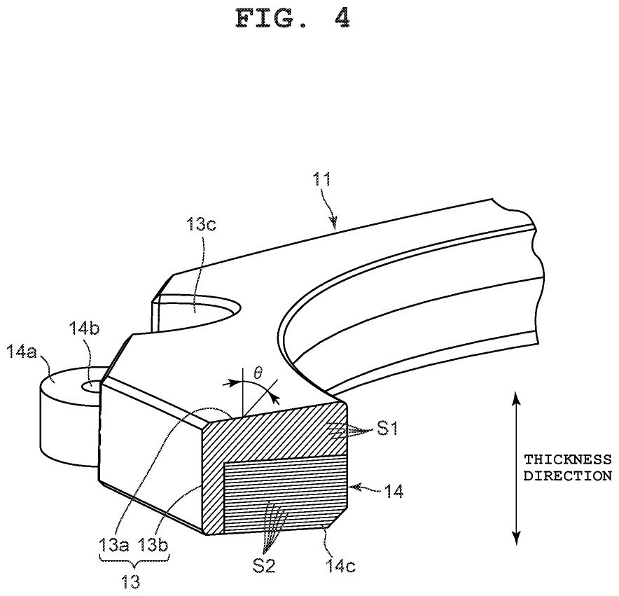

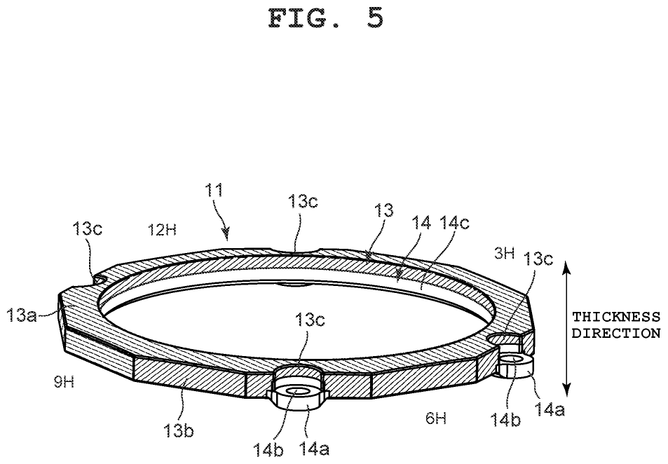

That is, the first fiber-reinforced resin body 13 has a structure where the plurality of glass fiber layers S1, which are glass fiber-reinforced resin sheets formed by glass fibers being solidified by epoxy resin, has been laminated while being inclined at the predetermined inclination angle θ with reference to the thickness direction of the first fiber-reinforced resin body 13 which is the front or back direction, or in other words, inclined at the predetermined inclination angle θ with respect to second fiber-reinforced resin sheets of the second fiber-reinforced resin body 14 described later, as shown in FIG. 4 and FIG. 5. In this embodiment, the glass fiber layers S1 which are the first fiber-reinforced resin sheets of the first fiber-reinforced resin body 13 have been inclined in the three o'clock direction of the wristwatch case 1.

On the twelve o'clock side and six o'clock side of the wristwatch case 1, the band attachment sections 2 are provided. To these band attachment sections 2, the watch bands (not shown) are attached. Because of this structure, external force is more likely to be exerted onto the three o'clock side and nine o'clock side of the wristwatch case 1. In consideration of this likelihood, the glass fiber layers S1 are structured to be laminated while being inclined at the predetermined inclination angle θ in the three o'clock direction, whereby the strength is increased.

Without this inclination, the strength of the first fiber-reinforced resin body 13 against external force exerted in the front or back direction is low because shear force which debonds the glass fiber layers S1 from one another is exerted when the external force is exerted onto the first fiber-reinforced resin body 13 in the front or back direction. However, in the present embodiment where the first fiber-reinforced resin body 13 has the structure where each glass fiber layer S1 has been inclined with reference to the front or back direction, the bonding area of an interface between adjacent glass fiber layers S1 is large by an amount equal to the inclination achieved with the inclination angle θ, whereby the bonding strength at the interface between the adjacent glass fiber layers S1 is high.

In this embodiment, the inclination angle θ of each glass fiber layer S1 is an inclination angle with reference to the front or back direction of the first fiber-reinforced resin body 13, which is within an angle range of 30 to 70 degrees with reference to the front or back direction (thickness direction) of the first fiber-reinforced resin body 13 and should preferably be, for example, an angle of 45 degrees, as shown in FIG. 4. As a result, the first fiber-reinforced resin body 13 is structured such that each end surface of the multiple laminated glass fiber layers S1 is exposed on the outer surfaces of the front surface section 13a and the side surface section 13b and can be seen from outside, which enhances the decorativeness and the design.

More specifically, on the front surface section 13a of the first fiber-reinforced resin body 13, end surfaces of the glass fiber layers S1 form, for example, a striped shape having parallel straight lines connecting the twelve o'clock side and the six o'clock side, as shown in FIG. 5. Also, on the side surface section 13b of the first fiber-reinforced resin body 13 excluding its portions on the three o'clock side and the nine o'clock side, end surfaces of the glass fiber layers S1 form a striped shape having parallel straight lines inclined at the predetermined inclination angle θ such as an angle of 45 degrees. In this embodiment, on the three o'clock side and nine o'clock side of the side surface section 13b, end surfaces of the glass fiber layers S1 form a striped shape having parallel straight lines extending in a direction perpendicular to the front or back direction of the first fiber-reinforced resin body 13.

Also, the first fiber-reinforced resin body 13 is colored such that end surfaces of the multiple laminated glass fiber layers S1 form a striped color pattern as a whole, as shown in FIG. 5. More specifically, when glass fibers are to be solidified by epoxy resin for the glass fiber layers S1, pigments are mixed into the epoxy resin, whereby these multiple glass fiber layers S1 are individually and differently colored. That is, each glass fiber layer S1 is colored in a different color.

On the other hand, the second fiber-reinforced resin body 14 is formed by a plurality of second fiber-reinforced resin sheets being laminated, as shown in FIG. 4. These second fiber-reinforced resin sheets are carbon fiber layers S2 which are carbon fiber-reinforced resin sheets using carbon fibers as reinforcement materials. More specifically, the second fiber-reinforced resin body 14 is a carbon fiber-reinforced resin sheet body (CFRP) formed by the carbon fiber layers S2, which are the plurality of second fiber-reinforced resin sheets, being laminated in a thickness direction of the second fiber-reinforced resin body 14 which is the front or back direction, and its cross-section has a substantially quadrilateral shape.

Since the second fiber-reinforced resin body 14 is formed by the plurality of carbon fiber layers S2, which are carbon fiber-reinforced resin sheets acquired by the solidification of carbon fibers by epoxy resin, being laminated in the front or back direction (thickness direction) of the second fiber-reinforced resin body 14, its compressive strength in the thickness direction and its tensile strength in a plane direction are higher than those of the first fiber-reinforced resin body 13, as shown in FIG. 4.

As such, the second fiber-reinforced resin body 14 has the structure where the carbon fiber layers S2 have been laminated in the front or back direction of the second fiber-reinforced resin body 14, and the first fiber-reinforced resin body 13 has the structure where the glass fiber layers S1 have been laminated while being inclined at the predetermined inclination angle θ such as an angle of 45 degrees with reference to the front or back direction of the first fiber-reinforced resin body 13, as shown in FIG. 4.

As a result, the second fiber-reinforced resin body 14 is formed such that the bonding area of an interface between adjacent carbon fiber layers S2 is larger than the bonding area of an interface between adjacent glass fiber layers S1 of the first fiber-reinforced resin body 13, whereby the bonding strength at the interface between the adjacent carbon fiber layers S2 is higher than the bonding strength at the interface between the adjacent glass fiber layers S1 of the first fiber-reinforced resin body 13, as shown in FIG. 4. As a result of this structure, the second fiber-reinforced resin body 14 is formed such that its compressive strength in the thickness direction and its tensile strength in the plane direction are higher than those of the first fiber-reinforced resin body 13.

The second fiber-reinforced resin body 14 is arranged in contact with the back surface side of the first fiber-reinforced resin body 13, or in other words, the undersurface of the front surface section 13a of the first fiber-reinforced resin body 13 and the inner surface of the side surface section 13b of the first fiber-reinforced resin body 13, and firmly bonded to the first fiber-reinforced resin body 13 by thermal compression bonding, as shown in FIG. 4. More specifically, the epoxy resin of the glass fiber layers S1 in the glass fiber-reinforced resin sheet body (GFRP) serving as the first fiber-reinforced resin body 13 and the epoxy resin of the carbon fiber layers S2 in the carbon fiber-reinforced sheet body (CFRP) serving as the second fiber-reinforced resin body 14 are melted and fixed to each other by thermal compression bonding, whereby the first fiber-reinforced resin body 13 and the second fiber-reinforced resin body 14 are firmly bonded to each other.

In this embodiment, the second fiber-reinforced resin body 14 is formed such that its thickness in the front or back direction is greater than the thickness of the front surface section 13a of the first fiber-reinforced resin body 13, and its undersurface is arranged to be flush with the lower end surface of the side surface section 13b of the first fiber-reinforced resin body 13, as shown in FIG. 4. As a result, the second fiber-reinforced resin body 14 is structured to be arranged under the back surface of the first fiber-reinforced resin body 13 and integrally bonded to the first fiber-reinforced resin body 13.

Also, the second fiber-reinforced resin body 14 includes a main body section 14c and a plurality of attachment projection sections 14a, as shown in FIG. 1 to FIG. 5. The main body section 14c has a substantially ring shape as a whole. The plurality of attachment projection sections 14a is provided on portions of the main body section 14c of the second fiber-reinforced resin body 14, or more specifically, side surface portions of the main body section 14c on the one o'clock side, the five o'clock side, the seven o'clock side, and the eleven o'clock side and protrudes sideward from the side surface section 13b of the first fiber-reinforced resin body 13.

More specifically, each attachment projection section 14a is formed in a cylindrical shape and provided projecting on the main body section 14c of the second fiber-reinforced resin body 14, as shown in FIG. 1 to FIG. 5. The thickness of each attachment projection section 14a is slightly less than the thickness of the second fiber-reinforced resin body 14.

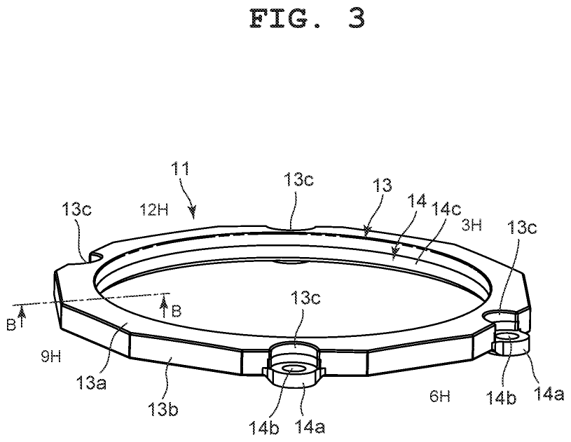

In this embodiment, each attachment projection section 14a is formed such that it has a circular shape in a planar view and located at a position one step lower than the upper surface of the second fiber-reinforced resin body 14 with half of its circular shape protruding from the side surface section 13b of the first fiber-reinforced resin body 13 and the other half projecting into the second fiber-reinforced resin body 14, as shown in FIG. 1 and FIG. 3. That is, bonding surfaces formed by the undersurface serving as the back surface of the front surface section 13a of the first fiber-reinforced resin body 13 and the upper surface serving as the front surface of the second fiber-reinforced resin body 14 are located higher than the upper surfaces serving as the front surfaces of the attachment projection sections 14a in the thickness direction of the second fiber-reinforced resin body 14.

In the side surface section 13b of the first fiber-reinforced resin body 13, semicircular cutout sections 13c are formed corresponding to the respective attachment projection sections 14a, as shown in FIG. 1 to FIG. 3. Also, in the attachment projection sections 14a, first screw insertion holes 14b into which the screw members 12 are inserted are provided penetrating in the thickness direction which is the front or back direction.

On the other hand, in portions of the outer case 7 of the case main body 5 located to the sides of the each band attachment section 2, that is, on the one o'clock side, five o'clock side, seven o'clock side, and eleven o'clock side of the outer case 7, screw attachment holes 7b are provided which are attachment holes to which the screw members 12 are attached, as shown in FIG. 1 and FIG. 2. These screw attachment holes 7b are holes provided extending from the upper surface of the outer case 7 toward the undersurface in a manner not to vertically penetrate the outer case 7.

Each screw attachment hole 7b includes a non-thread portion formed on the upper side and having no thread groove, and a thread portion formed on the lower side and having a thread groove, which are coaxially located, as shown in FIG. 2. In association with the above-described structure, in the plate section 10a of the first exterior member 10, second screw insertion holes 10d into which the screw members 12 are inserted are provided coaxially with the screw attachment holes 7b of the outer case 7 and the first screw insertion holes 14b of the second exterior member 11.

Each screw member 12 includes a head section 12a, a neck section 12b, and a thread section 12c, as shown in FIG. 1 and

FIG. 2. The head section 12a is formed such that its outer diameter is substantially equal to or slightly shorter than the outer diameter of each attachment projection section 14a of the second fiber-reinforced resin body 14. As a result, the head section 12a is structured such that its outer circumferential surface does not come in contact with the inner circumferential surface of the corresponding semicircular cutout section 13c formed in the first fiber-reinforced resin body 13.

In addition, the head section 12a is formed such that its length in an axial direction, that is, its length in a thickness direction of the second exterior member 11 is substantially equal to the thickness of the corresponding attachment projection section 14a, and slightly shorter than the length from the upper surface of the attachment projection section 14a to the upper surface of the second exterior member 11, that is, the upper surface of the front surface section 13a of the first fiber-reinforced resin body 13, as shown in FIG. 1 and FIG. 2. As a result, the head section 12a is structured such that its upper surface does not project above the upper surface of the front surface section 13a of the first fiber-reinforced resin body 13.

The neck section 12b is formed such that its outer diameter is slightly shorter than the inner diameter of the first screw insertion hole 14b of the corresponding attachment projection section 14a, as shown in FIG. 2. Also, this neck section 12b is formed such that its axial length, that is, its vertical length is slightly longer than the sum of the depth of the first screw insertion hole 14b of the attachment projection section 14a and the depth of the corresponding second screw insertion hole 10d in the plate section 10a of the first exterior member 10. As a result, this neck section 12b is structured such that, when the head section 12a is pressed against the attachment projection section 14a, the lower end portion of the neck section 12b is inserted into a non-thread portion on the upper side of the corresponding screw attachment hole 7b.

The thread section 12c is formed such that its outer diameter is slightly shorter than the outer diameter of the neck section 12b, and its axial length is shorter than the axial length of a thread portion on the lower side of the corresponding screw attachment hole 7b in the outer case 7, as shown in FIG. 2. This thread section 12c is structured to be screwed into the thread portion of the screw attachment hole 7b through the non-thread portion thereof. In addition, this thread section 12c is structured such that its lower end does not reach the bottom of the thread portion on the lower side of the screw attachment hole 7b.

That is, the screw members 12 are structured such that they fix the exterior member 6 to the case main body 5 when the exterior member 6 is arranged on the case main body 5a and, in this state, the thread sections 12c are inserted into the second screw insertion holes 10d of the first exterior member 10 through the first screw insertion holes 14b in the attachment projection sections 14a of the second fiber-reinforced resin body 14 in the second exterior member 11 of the exterior member 6 and screwed into the thread portions of the screw attachment holes 7b in the outer case 7 so that the screw members 12 are tightened, as shown in FIG. 2.

That is, the screw members 12 are structured such that, when the thread sections 12c are screwed into and tightened in the screw attachment holes 7b of the outer case 7, the head sections 12a are pressed against the attachment projection sections 14a of the second fiber-reinforced resin body 14 and thereby unfailingly press the first exterior member 10 against the outer case 7 via the second exterior member 11, whereby the exterior member 6 is firmly attached to the case main body 5, as shown in FIG. 2.

Also, the screw members 12 are structured such that, even when the head sections 12a are pressed against the upper surfaces of the attachment projection sections 14a of the second fiber-reinforced resin body 14 and rotated by the screw members 12 being tightened, the rotations of the head sections 12a do not cause the undersurface of the front surface section 13a of the first fiber-reinforced resin body 13 and the upper surface of the second fiber-reinforced resin body 14 to be debonded from each other because the upper surfaces of the attachment projection sections 14a are located at positions one step lower than the upper surface of the second fiber-reinforced resin body 14, or in other words, the bonding surfaces formed by the undersurface of the front surface section 13a of the first fiber-reinforced resin body 13 and the upper surface of the second fiber-reinforced resin body 14 are located at positions higher than the upper surfaces of the attachment projection sections 14a in the thickness direction of the second fiber-reinforced resin body 14, as shown in FIG. 2.

Also, the second exterior member 11 is structured such that, when the plurality of attachment projection sections 14a provided on the one o'clock side, five o'clock side, seven o'clock side, and eleven o'clock side of the second fiber-reinforced resin body 14 is pressed against the outer case 7 of the case main body 5 by the screw members 12, no shear force is exerted on the second fiber-reinforced resin body 14 so that the carbon fiber layers S2 are not debonded from one another, and force in a direction in which the carbon fiber layers S2 are compressed against one another is exerted, as shown in FIG. 1 and FIG. 2. By this structure, the sufficient strength of the plurality of attachment projection sections 14a of the second fiber-reinforced resin body 14 is ensured. Thus, the plurality of attachment projection sections 14a is not damaged even when they are pressed against the outer case 7 of the case main body 5 by the screw members 12. Accordingly, by the strength against the tightening force of the screw members 12 being enhanced, the second exterior member 11 is structured to be reliably and firmly attached to the outer case 7, as shown in FIG. 1 and FIG. 2.

Also, the screw members 12 are structured such that, when the thread sections 12c are tightened by being screwed into the screw attachment holes 7b of the outer case 7 and the head sections 12a are pressed against the attachment projection sections 14a of the second fiber-reinforced resin body 14, the outer case 7 is pulled up toward the first exterior member 10, the projection section 8b of the inner case 8 is pressed upward by the recess section 7a of the outer case 7, and the inner case 8 is pressed against the plate section 10a of the first exterior member 10, whereby the exterior member 6 is reliably and firmly attached to the case main body 5, as shown in FIG. 2.

Next, an assembly procedure for this watch case 1 is described.

In this embodiment, first, the case main body 5 is assembled. In this assembly, the inner case 8 made of a hard synthetic resin is inserted from above into the outer case 7 made of a metal such as stainless steel, and the projection section 8b of the inner case 8 is engaged with the recess section 7a of the outer case 7. As a result, the inner case 8 is attached to the inside of the outer case 7 in a manner not to be downwardly slipped out, whereby the case main body 5 is assembled.

In this state, the upper end surface of the outer case 7 has been arranged slightly lower than the upper end surface of the inner case 8. Then, the watch module (not shown) is mounted in the inner case 8 of the case main body 5, and the plurality of switch buttons 3 is attached to the outer circumferential portions of the case main body 5. Subsequently, the outer case 6 is attached to the case main body 5. Before this attachment, the watch glass 4 and the packing 4a are fitted into and attached to the cylindrical section 10b of the first exterior member 10 made of a metal such as stainless steel.

In this state, the waterproof ring 9 is arranged in the upper end surface of the inner case 8, and the plate section 10a of the first exterior member 10 is arranged on and straddles the upper end surface of the outer case 7 and the upper end surface of the inner case 8. Here, the restriction section 10c formed on the inner circumferential rim of the plate section 10a of the first exterior member 10 is arranged to come in contact with the inner circumferential surface of the inner case 8, whereby the first exterior member 10 is arranged on the case main body 5 with its position in radial directions being restricted. Also, here, the second screw insertion holes 10d of the first exterior member 10 are arranged coaxially corresponding to the screw attachment holes 7b of the outer case 7.

In this state, the second exterior member 11 is arranged on the first exterior member 10. Before this arrangement, the second exterior member 11 is manufactured in advance. In this manufacture, first, the first fiber-reinforced resin body 13 and second fiber-reinforced resin body 14 of the second exterior member 11 are manufactured. More specifically, in the manufacture of the first fiber-reinforced resin body 13, the plurality of glass fiber layers S1 formed by glass fibers being solidified by epoxy resin are laminated while being inclined at the predetermined inclination angle θ such as an angle of 45 degrees with reference to the front or back direction of the first fiber-reinforced resin body 13, and formed into a substantially ring shape which includes the front surface section 13a and the side surface section 13b and whose cross-section has a substantially eave shape.

Also, in the manufacture of the second fiber-reinforced resin body 14, the carbon fiber layers S2 formed by carbon fibers being solidified by epoxy resin are laminated in the front or back direction of the second fiber-reinforced resin body 14, and formed into a substantially ring shape whose cross-section has a substantially quadrilateral shape. Then, the second fiber-reinforced resin body 14 is arranged to come in contact with the undersurface of the front surface section 13a of the first fiber-reinforced resin body 13 and the inner surface of the side surface section 13b of the first fiber-reinforced resin body 13, and the first fiber-reinforced resin body 13 and the second fiber-reinforced resin body 14 are bonded to each other by thermal compression bonding.

In this thermal compression bonding, the epoxy resin of the glass fiber layers S1 in the glass fiber-reinforced resin sheet body (GFRP) serving as the first fiber-reinforced resin body 13 and the epoxy resin of the carbon fiber layers S2 in the carbon fiber-reinforced sheet body (CFRP) serving as the second fiber-reinforced resin body 14 are melted and firmly fixed to each other by thermal compression bonding. In this state, the undersurface of the second fiber-reinforced resin body 14 has been arranged to be flush with the lower end surface of the side surface section 13b of the first fiber-reinforced resin body 13, and the second fiber-reinforced resin body 14 has been arranged under the back surface of the first fiber-reinforced resin body 13 such that it is integral with the first fiber-reinforced resin body 13.

Then, the second exterior member 11 acquired by the first fiber-reinforced resin body 13 and the second fiber-reinforced resin body 14 being bonded to each other is fitted around the outer circumferential portion of the cylindrical section 10b of the first exterior member 10, and thereby arranged on the plate section 10a of the first exterior member 10. In this state, the first screw insertion holes 14b of the plurality of attachment projection sections 14a provided on the second fiber-reinforced resin body 14 of the second exterior member 11 are positioned to coaxially correspond to the plurality of second screw insertion holes 10d formed in the plate section l0a of the first exterior member 10.

In this state, the second exterior member 11 is attached to the case main body 5 together with the first exterior member 10 by the plurality of screw members 12. In this attachment, the thread sections 12c of the plurality of screw members 12 are inserted into the plurality of second screw insertion holes 10d in the plate section l0a of the first exterior member 10 through the first screw insertion holes 14b of the plurality of attachment projection sections 14a provided on the second fiber-reinforced resin body 14 of the second exterior member 11, and screwed into and tightened in the plurality of screw attachment holes 7b formed in the outer case 7 of the case main body 5.

As a result, the head sections 12a of the plurality of screw members 12 are pressed against the plurality of attachment projection sections 14a of the second fiber-reinforced resin body 14, and thereby press the plate section 10a of the first exterior member 10 against the outer case 7. Here, by having the structure where carbon fibers have been laminated in the front or back direction of the second fiber-reinforced resin body 14, the second fiber-reinforced resin body 14 is higher in strength than the first fiber-reinforced resin body 13. Therefore, the attachment projection sections 14a of the second fiber-reinforced resin body 14 are not damaged even when they are pressed against the outer case 7 via the first exterior member 10 by the head sections 12a of the screw members 12. By this structure, the attachment strength of the second exterior member 11 is high, whereby the impact resistance is improved.

Also, even when the screw members 12 are tightened and their head sections 12a are pressed against the upper surfaces of the attachment projection sections 14a of the second fiber-reinforced resin body 14 and rotated, since the upper surfaces of the attachment projection sections 14a are at the positions one step lower than the upper surface of the second fiber-reinforced resin body 14, that is, since the bonding surfaces formed by the undersurface of the front surface section 13a of the first fiber-reinforced resin body 13 and the upper surface of the second fiber-reinforced resin body 14 are at the positions higher than the upper surfaces of attachment projection sections 14a in the thickness direction of the second fiber-reinforced resin body 14, the debonding of the undersurface of the front surface section 13a of the first fiber-reinforced resin body 13 and the upper surface of the second fiber-reinforced resin body 14 due to the contact rotations of the head sections 12a can be prevented.

That is, if the bonding surfaces formed by the undersurface of the front surface section 13a of the first fiber-reinforced resin body 13 and the upper surface of the second fiber-reinforced resin body 14 are at the same height as the undersurfaces of the head sections 12a of the screw members 12, the undersurface of the front surface section 13a of the first fiber-reinforced resin body 13 and the upper surface of the second fiber-reinforced resin body 14 could be debonded from each other by the rotations of the head sections 12a when the screw members 12 are tightened and the undersurfaces of their head sections 12a are pressed against the upper surfaces of the attachment projection sections 14a of the second fiber-reinforced resin body 14 and rotated. Thus, the bonding surfaces formed by the undersurface of the front surface section 13a of the first fiber-reinforced resin body 13 and the upper surface of the second fiber-reinforced resin body 14 are required to be at positions different from those of the undersurfaces of the head sections 12a, that is, positions higher than the undersurfaces of the head sections 12a.

When the head sections 12a of the plurality of screw members 12 are pressed against the plurality of attachment projection sections 14a of the second fiber-reinforced resin body 14, the outer case 7 is pulled up toward the plate section 10a of the first exterior member 10 with the plate section 10a of the first exterior member 10 pressing the waterproof ring 9 against the upper end surface of the inner case 8. As a result, the recess section 7a of the outer case 7 presses the projection section 8b of the inner case 8 upward, and thereby presses the inner case 8 against the plate section 10a of the first exterior member 10.

In addition, the waterproof ring 9 is held and compressed between the plate section l0a of the first exterior member 10 and the inner case 8, so that waterproofing between the plate section l0a of the first exterior member 10 and the inner case 8 is achieved. As a result of the above-described procedure, the exterior member 6 is reliably and firmly attached to the case main body 5, whereby the assembly of the wristwatch case 1 is completed.

Next, the mechanism of the wristwatch case 1 is described.

In this wristwatch case 1, the first fiber-reinforced resin body 13 of the second exterior member 11 has the structure where the glass fiber layers S1 formed by glass fibers being solidified by epoxy resin have been laminated while being inclined at the predetermined inclination angle θ such as an angle of 45 degrees with reference to the front or back direction of the first fiber-reinforced resin body 13. Accordingly, end surfaces of the multiple glass fiber layers S1 are exposed on the outer surfaces of the front surface section 13a and the side surface section 13b and therefore can be seen from outside.

More specifically, on the front surface section 13a of the first fiber-reinforced resin body 13, end surfaces of the multiple glass fiber layers S1 form, for example, a striped shape having parallel straight lines connecting the twelve o'clock side and the six o'clock side, as shown in FIG. 5. Also, on the side surface section 13b of the first fiber-reinforced resin body 13 excluding its portions on the three o'clock side and the nine o'clock side, end surfaces of the multiple glass fiber layers S1 form a striped shape having parallel straight lines inclined at the predetermined inclination angle θ such as an angle of 45 degrees. Moreover, on the three o'clock side and nine o'clock side of the side surface section 13b, end surfaces of the multiple glass fiber layers S1 form a striped shape having parallel straight lines extending in the direction perpendicular to the front or back direction of the first fiber-reinforced resin body 13. As a result of this structure, the decorativeness and design of the first fiber-reinforced resin body 13 are enhanced.

Also, in the case of this first fiber-reinforced resin body 13, when glass fibers are to be solidified by epoxy resin so as to form the glass fiber layers S1, pigments are mixed into the epoxy resin, whereby the glass fiber layers S1 are differently colored for each glass fiber layer S1, as shown in FIG. 5. As a result, the first fiber-reinforced resin body 13 is colored such that end surfaces of the multiple laminated glass fiber layers S1 form a striped color pattern. As a result of this structure, the decorativeness and design of the first fiber-reinforced resin body 13 are further enhanced.

In the case of the exterior member for wristwatches described in Japanese Patent Application Laid-Open (Kokai) Publication No. 2005-114495, thermosetting resins are provided on the front and back surfaces of a carbon fiber-reinforced resin sheet formed by carbon fibers being laminated in the front or back direction, whereby weight saving can be achieved. However, this structure has a problem in that sufficient strength cannot be acquired and therefore sufficient impact resistance cannot be ensured.

In contrast, the second exterior member 11 of the wristwatch case 1 according to the present embodiment includes the first fiber-reinforced resin body 13 formed by the glass fiber layers S1 which are a plurality of first fiber-reinforced resin sheets being laminated, and the second fiber-reinforced resin body 14 formed by the carbon fiber layers S2 which are a plurality of second fiber-reinforced resin sheets being laminated, in which the glass fiber layers S1 of the first fiber-reinforced resin body 13 have been laminated while being inclined with respect to the carbon fiber layers S2 of the second fiber-reinforced resin body 14. As a result of this structure, the design is enhanced, and the strength is improved to enhance the impact resistance.

That is, in this second exterior member 11, the glass fiber layers S1 of the first fiber-reinforced resin body 13 have been laminated while being inclined with respect to the carbon fiber layers S2 of the second fiber-reinforced resin body 14, and therefore the compressive strength of the second fiber-reinforced resin body 14 in the thickness direction which is the front or back direction and the tensile strength thereof in the plane direction are higher than those of the first fiber-reinforced resin body 13, whereby the impact resistance is enhanced.

Also, in this second exterior member 11, the glass fiber layers S1 which are the first fiber-reinforced resin sheets of the first fiber-reinforced resin body 13 have been laminated while being inclined with reference to the thickness direction of the first fiber-reinforced resin body 13 which is the front or back direction, and the carbon fiber layers S2 which are the second fiber-reinforced resin sheets of the second fiber-reinforced resin body 14 have been laminated in the thickness direction of the second fiber-reinforced resin body 14 which is the front or back direction, whereby the design is enhanced, and the strength is improved to enhance the impact resistance.

That is, this second exterior member 11 has the structure where the glass fiber layers S1 of the first fiber-reinforced resin body 13 have been laminated while being inclined at the predetermined inclination angle θ with reference to the thickness direction of the first fiber-reinforced resin body 13 and these layers have been aligned in the direction perpendicular to the front or back direction, whereby end surfaces of the laminated glass fiber layers S1 are exposed on the front and side surfaces of the first fiber-reinforced resin body 13. As a result of this structure, end surfaces of the multiple laminated glass fiber layers S1 form a pattern, whereby the decorativeness and design are enhanced

Also, on the front surface of the first fiber-reinforced resin body 13, end surfaces of the multiple glass fiber layers S1 form, for example, a striped shape having parallel straight lines connecting the twelve o'clock side and the six o'clock side. In addition, on the side surface of the first fiber-reinforced resin body 13 excluding its portions on the three o'clock side and the nine o'clock side, end surfaces of the multiple glass fiber layers S1 form a striped shape having parallel straight lines inclined at the predetermined inclination angle θ such as an angle of 45 degrees. Moreover, on the three o'clock side and nine o'clock side of the side surface, end surfaces of the multiple glass fiber layers S1 form a striped shape having parallel straight lines extending in the direction perpendicular to the front or back direction of the first fiber-reinforced resin body 13. As a result of this structure, end surfaces of the multiple glass fiber layers S1 favorably form striped patterns, whereby the decorativeness and the design are enhanced.

Also, in the second exterior member 11, the carbon fiber layers S2 of the second fiber-reinforced resin body 14 have been laminated in the thickness direction of the second fiber-reinforced resin body 14 which is the front or back direction. As a result of this structure, their strength is enhanced higher than that of the first fiber-reinforced resin body 13 formed using glass fibers. That is, in the second exterior member 11, since the second fiber-reinforced resin body 14 has the structure where the carbon fiber layers S2 formed using carbon fibers as reinforcement materials have been laminated in the thickness direction of the second fiber-reinforced resin body 14, the compressive strength of the second fiber-reinforced resin body 14 in the thickness direction which is the front or back direction and the tensile strength thereof in the plane direction are enhanced higher than those of the first fiber-reinforced resin body 13, whereby the impact resistance is enhanced.

That is, the second fiber-reinforced resin body 14 has the structure where the carbon fiber layers S2 have been laminated in the front or back direction of the second fiber-reinforced resin body 14, and the first fiber-reinforced resin body 13 has the structure where the glass fiber layers S1 have been laminated while being inclined at the predetermined inclination angle θ such as an angle of 45 degrees with reference to the front or back direction of the first fiber-reinforced resin body 13. As a result of these structures, the bonding area of each interface among the carbon fiber layers S2 of the second fiber-reinforced resin body 14 is larger than that of each interface among the glass fiber layers S1 of the first fiber-reinforced resin body 13.

As a result, bonding strength at each interface among the carbon fiber layers S2 of the second fiber-reinforced resin body 14 is higher than that at each interface among the glass fiber layers S1 of the first fiber-reinforced resin body 13, whereby the compressive strength of the second fiber-reinforced resin body 14 in the thickness direction and the tensile strength thereof in the plane direction are enhanced higher than the compressive strength of the first fiber-reinforced resin body 13 in the thickness direction and the tensile strength thereof in the plane direction.

Also, in the case of this second exterior member 11, the first fiber-reinforced resin body 13 is colored such that each glass fiber layer S1 is in a different color, whereby end surfaces of these multiple glass fiber layers S1 forma striped color pattern. As a result of this structure, the decorativeness and the design are further enhanced. That is, in the case of the first fiber-reinforced resin body 13, when glass fibers are to be solidified by epoxy resin, pigments are mixed into the epoxy resin, and the glass fiber layers S1 are colored for each layer, whereby a striped pattern is favorably formed in color by end surfaces of the multiple glass fiber layers S1.

Also, in the case of this second exterior member 11, the second fiber-reinforced resin body 14 is bonded to the back surface side of the first fiber-reinforced resin body 13 by thermo compression bonding. As a result of this structure, the second fiber-reinforced resin body 14 is reliably and firmly bonded to the first fiber-reinforced resin body 13 with it being arranged under the back surface side of the first fiber-reinforced resin body 13.

That is, in the case of this second exterior member 11, the first fiber-reinforced resin body 13 and the second fiber-reinforced resin body 14 are bonded to each other by thermo compression bonding, whereby the epoxy resin of the glass fiber layers S1 in the glass fiber-reinforced resin sheet body (GFRP) serving as the first fiber-reinforced resin body 13 and the epoxy resin of the carbon fiber layers S2 in the carbon fiber-reinforced sheet body (CFRP) serving as the second fiber-reinforced resin body 14 are melted and fixed to each other. As a result of this structure, the first fiber-reinforced resin body 13 and the second fiber-reinforced resin body 14 are firmly bonded to each other.

Also, in the second exterior member 11, the first fiber-reinforced resin body 13 includes the front surface section 13a and the side surface section 13b, and the second fiber-reinforced resin body 14 includes the attachment projection sections 14a which protrude sideward from the side surface section 13b of the first fiber-reinforced resin body 13. As a result of this structure, by the attachment projection sections 14a formed on the second fiber-reinforced resin body 14 whose strength is higher than that of the first fiber-reinforced-resin body 13, the attachment strength is enhanced and the second fiber-reinforced resin body 14 is reliably and firmly attached to the case main body 5.

Moreover, in the second exterior member 11, the bonding surfaces formed by the undersurface serving as the back surface of the front surface section 13a of the first fiber-reinforced resin body 13 and the upper surface serving as the front surface of the second fiber-reinforced resin body 14 are located higher than the upper surfaces serving as the front surfaces of the attachment projection sections 14a in the thickness direction of the second fiber-reinforced resin body 14. As a result of this structure, the debonding of the undersurface of the front surface section 13a of the first fiber-reinforced resin body 13 and the upper surface of the second fiber-reinforced resin body 14 due to the rotations of the head sections 12a when the screw members 12 are tightened is prevented.

Furthermore, in the case of this second exterior member 11, the first screw insertion holes 14b are formed penetrating the attachment projection sections 14a of the second fiber-reinforced resin body 14 in the thickness direction of the second fiber-reinforced resin body 14 which is the front or back direction, and the screw members 12 which are fastening members are inserted into these first screw insertion holes 14b. As a result of this structure, by the screw members 12, the second fiber-reinforced resin body 14 is reliably and firmly attached to the case main body 5.

Also, the wristwatch case 1 includes the second exterior member 11 and the case main body 5 on the front surface of which the second exterior member 11 is arranged. Accordingly, its design is enhanced by the first fiber-reinforced resin body 13 of the second exterior member 11. In addition, its strength is increased by the second fiber-reinforced resin body 14 of the second exterior member 11 which increases the strength more than the first fiber-reinforced resin body 13. As a result of this structure, by the attachment projection sections 14a of the second fiber-reinforced resin body 14, the strength of the attachment of the second exterior member 11 to the case main body 5 is increased, which enhances the impact resistance.

Moreover, in the case of this wristwatch case 1, the screw attachment holes 7b are formed in the case main body 5 while corresponding to the first screw insertion holes 14b in the attachment projection sections 14a of the second fiber-reinforced resin body 14. Accordingly, the screw members 12 serving as fastening members are inserted into the first screw insertion holes 14b in the attachment projection sections 14a of the second fiber-reinforced resin body 14 and screwed into the screw attachment holes 7b in the case main body 5, whereby the second exterior member 11 is reliably and firmly attached to the case main body 5.

That is, in this wristwatch case 1, the second exterior member 11 is attached to the case main body 5 by the screw members 12 serving as fastening members, which are inserted into the first screw insertion holes 14b in the attachment projection sections 14a of the second fiber-reinforced resin body 14 and attached to the screw attachment holes 7b of the case main body 5. As a result of this structure, the second exterior member 11 is reliably and firmly attached to the case main body 5.

Moreover, in this wristwatch case 1, the screw members 12 include the head sections 12a, the neck sections 12b, and the thread sections 12c. When the thread sections 12c are screwed into the screw attachment holes 7b in the outer case 7 of the case main body 5 through the first screw insertion holes 14b in the attachment projection sections 14a of the second fiber-reinforced resin body 14 of the second exterior member 11 and tightened, the head sections 12a press the attachment projection sections 14a of the second fiber-reinforced resin body 14 against the outer case 7. As a result of this structure, the second exterior member 11 is reliably and firmly attached to the case main body 5.

That is, in this wristwatch case 1, each attachment projection section 14a of the second fiber-reinforced resin body 14 against which the head section 12a of the corresponding screw member 12 is pressed has the structure where carbon fibers have been laminated in the front or back direction of the second fiber-reinforced resin body 14, whereby the strength of the attachment projection sections 14a of the second fiber-reinforced resin body 14 is higher than that of the first fiber-reinforced resin body 13. As a result of this structure, the strength of the attachment of the second exterior member 11 to the case main body 5 is increased, whereby the impact resistance is enhanced.

Furthermore, in this wristwatch case 1, the glass fiber layers S1 which are the first fiber-reinforced resin sheets of the first fiber-reinforced resin body 13 have been inclined in the three o'clock direction of the wristwatch case 1, which increases the strength of the second exterior member 11. That is, in this wristwatch case 1, the band attachment sections 2 to which the watch bands (not shown) are attached are provided on the twelve o'clock side and two o'clock side of the wristwatch case 1, because of which external force is more likely to be exerted onto the three o'clock side and nine o'clock side of the wristwatch case 1. However, since the glass fiber layers S1 are laminated while being inclined at the predetermined inclination angle θ in the three o'clock direction, the strength is increased

In the above-described embodiment, the first fiber-reinforced resin body 13 is formed by only the glass fiber layers S1 acquired by glass fibers being solidified by epoxy resin. However, the present invention is not limited thereto. For example, a composite fiber-reinforced resin body may be adopted as this first fiber-reinforced resin body, which is a combination of glass fiber layers acquired by glass fibers being solidified by epoxy resin and carbon fiber layers acquired by carbon fibers being solidified by epoxy resin.

In that case, glass fiber-reinforced resin sheets using glass fibers as reinforcement materials and carbon fiber-reinforced resin sheets using carbon fibers as reinforcement materials are laminated to form the first fiber-reinforced resin body 13. That is, a plurality of first fiber-reinforced resin sheets using glass fiber-reinforced resin sheets and carbon fiber-reinforced resin sheets is formed.

This composite fiber-reinforced resin body is also required to have a structure where glass fiber layers and carbon fiber layers have been laminated in a direction perpendicular to the front or back direction of the composite fiber-reinforced resin body while being inclined at the predetermined inclination angle θ with reference to the thickness direction of the composite fiber-reinforced resin body which is the front or back direction. With this composite fiber-reinforced resin body, the black color is expressed by the carbon fiber layers, and therefore the glass fiber layers are not required to be colored in black.

Also, in the above-described embodiment, the second fiber-reinforced resin body 14 has the structure where the carbon fiber layers S2 have been laminated in the front or back direction of the second fiber-reinforced resin body 14. However, these fiber-reinforced resin layers of the present invention are not necessarily required to be the carbon fiber layers S2 and may be, for example, glass fiber layers using glass fibers, boron fiber layers using boron fibers, or aramid fiber layers using aramid fibers.

Moreover, in the above-described embodiment, the first fiber-reinforced resin body 13, in which the glass fiber-reinforced resin sheets (glass fiber layers S1) using glass fibers that are reinforcement materials have been laminated, has been described as the first fiber resin body of the present invention, and the second fiber-reinforced resin body 14, in which the carbon fiber-reinforced resin sheets (carbon fiber layers S2) using carbon fibers that are reinforcement materials have been laminated, has been described as the second fiber resin body of the present invention. However, the first fiber resin body and the second fiber resin body of the present invention are not limited thereto. That is, the main purpose of using fibers (such as glass fibers) for the first fiber resin sheets that constitute the first fiber resin body may be a purpose other than the enhancement of the strength of the first fiber resin sheets. Similarly, the main purpose of using fibers (such as carbon fibers) for the second fiber resin sheets that constitute the second fiber resin body may be a purposes other than the enhancement of the strength of the second fiber resin sheets.

Furthermore, in the above-described embodiment, the present invention has been applied in a wristwatch. However, the present invention is not necessarily required to be applied in a wristwatch. For example, the present invention is applicable to various types of timepieces such as a travel watch, an alarm clock, a table clock, and a wall clock. Furthermore, the present invention is not necessarily required to be applied in timepieces, and can be applied in electronic devices such as a portable telephone and a portable terminal device.

While the present invention has been described with reference to the preferred embodiments, it is intended that the invention be not limited by any of the details of the description therein but includes all the embodiments which fall within the scope of the appended claims.

What is claimed is:

1. An exterior member comprising:
a first fiber resin body formed by a plurality of first fiber resin sheets being laminated; and
a second fiber resin body formed by a plurality of second fiber resin sheets being laminated,
wherein the first fiber resin sheets of the first fiber resin body are laminated while being inclined with respect to the second fiber resin sheets of the second fiber resin body.

2. The exterior member according to claim 1, wherein the first fiber resin sheets of the first fiber resin body are laminated while being inclined with reference to a thickness direction of the first fiber resin body, and
wherein the second fiber resin sheets of the second fiber resin body are laminated in a thickness direction of the second fiber resin body.

3. The exterior member according to claim 1, wherein the first fiber resin sheets of the first fiber resin body are glass fiber-reinforced resin sheets using glass fibers that are reinforcement materials, and
wherein the second fiber resin sheets of the second fiber resin body are carbon fiber-reinforced resin sheets using carbon fibers that are reinforcement materials.

4. The exterior member according to claim 2, wherein the first fiber resin sheets of the first fiber resin body are glass fiber-reinforced resin sheets using glass fibers that are reinforcement materials, and
wherein the second fiber resin sheets of the second fiber resin body are carbon fiber-reinforced resin sheets using carbon fibers that are reinforcement materials.

5. The exterior member according to claim 1, wherein the first fiber resin sheets of the first fiber resin body are glass fiber-reinforced resin sheets using glass fibers that are reinforcement materials and carbon fiber-reinforced resin sheets using carbon fibers that are reinforcement materials, and
wherein the second fiber resin sheets of the second fiber resin body are carbon fiber-reinforced resin sheets using carbon fibers that are reinforcement materials.

6. The exterior member according to claim 2, wherein the first fiber resin sheets of the first fiber resin body are glass fiber-reinforced resin sheets using glass fibers that are reinforcement materials and carbon fiber-reinforced resin sheets using carbon fibers that are reinforcement materials, and
wherein the second fiber resin sheets of the second fiber resin body are carbon fiber-reinforced resin sheets using carbon fibers that are reinforcement materials.

7. The exterior member according to claim 1, wherein the first fiber resin body is formed by lamination of first fiber resin sheets acquired by fibers being solidified by resin, and
wherein the laminated first fiber resin sheets are individually colored.

8. The exterior member according to claim 2, wherein the first fiber resin body is formed by lamination of first fiber resin sheets acquired by fibers being solidified by resin, and
wherein the laminated first fiber resin sheets are individually colored.

9. The exterior member according to claim 1, wherein the second fiber resin body is bonded to a back surface side of the first fiber resin body by thermal compression bonding.

10. The exterior member according to claim 2, wherein the second fiber resin body is bonded to a back surface side of the first fiber resin body by thermal compression bonding.

11. The exterior member according to claim 1, wherein the first fiber resin body has a front surface portion and a side surface portion, and
wherein the second fiber resin body has an attachment projection portion which protrudes sideward from the side surface portion of the first fiber resin body.

12. The exterior member according to claim 2, wherein the first fiber resin body has a front surface portion and a side surface portion, and
wherein the second fiber resin body has an attachment projection portion which protrudes sideward from the side surface portion of the first fiber resin body.

13. The exterior member according to claim 11, wherein bonding surfaces formed by a back surface of the first fiber resin body and a front surface of the second fiber resin body are at positions higher than a front surface of the attachment projection portion in a thickness direction of the second fiber resin body.

14. The exterior member according to claim 12, wherein bonding surfaces formed by a back surface of the first fiber resin body and a front surface of the second fiber resin body are at positions higher than a front surface of the attachment projection portion in the thickness direction of the second fiber resin body.

15. The exterior member according to claim 11, wherein the attachment projection portion of the second fiber resin body has an insertion hole provided penetrating in a thickness direction of the second fiber resin body which is a front or back direction.

16. A case comprising:
the exterior member according to claim 1; and
a case main body on a front surface of which the exterior member is arranged.

17. The case according to claim 16, wherein the case main body has an attachment hole formed therein which corresponds to an insertion hole penetrating an attachment projection portion formed on the second fiber resin body and protruding sideward from a side surface portion of the first fiber resin body.

18. The case according to claim 17, wherein the exterior member is attached to the case main body by a fastening member which is inserted into the insertion hole in the attachment projection portion of the second fiber resin body and attached to the attachment hole of the case main body.

19. The case according to claim 16, wherein the first fiber resin sheets of the first fiber resin body are inclined in a three o'clock direction.

20. A timepiece comprising the case according to claim 16.
